(19) United States
(12) Patent Application Publication
(10) Pub. No.: US 2007/0054467 A1
(43) Pub. Date: Mar. 8, 2007

(54) Methods for integrating lattice-mismatched semiconductor structure on insulators

(75) Inventors: Matthew T. Currie, Brookline, MA (US); Anthony J. Lochtefeld, Somerville, MA (US); Zhiyuan Cheng, Lincoln, MA (US); Thomas A. Langdo, Framingham, MA (US)

Correspondence Address: GOODWIN PROCTER LLP;PATENT ADMINISTRATOR, EXCHANGE PLACE, BOSTON, MA, 02109-2881, US

(73) Assignee: AmberWave Systems Corporation, Salem, NH (US)

(21) Appl. No.: 11/221,064

(22) Filed: Sep. 7, 2005

(51) Int. Cl. H01L 21/30

(52) U.S. Cl. 438/458; 257/E21.568

(57) ABSTRACT

Monolithic lattice-mismatched semiconductor heterostructures are fabricated by bonding patterned substrates with alternative active-area materials formed thereon to a rigid dielectric platform and then removing the highly-defective interface areas along with the underlying substrates to produce alternative active-area regions disposed over the insulator and substantially exhausted of misfit and threading dislocations.

### FIELD OF THE INVENTION

This invention relates generally to lattice-mismatched semiconductor heterostructures and, specifically, to methods and materials for formation of integrated structures including alternative active-area materials on insulators.

### BACKGROUND OF THE INVENTION

The increasing operating speeds and computing power of microelectronic devices have recently given rise to the need for an increase in the complexity and functionality of the semiconductor structures from which these devices are fabricated. Hetero-integration of dissimilar semiconductor materials, for example, III-V materials, such as gallium arsenide, gallium nitride, indium aluminum arsenide, and/or germanium with silicon, siticon-on-insulator, or silicon-germanium substrates, is an attractive path for increasing the functionality and performance of the CMOS platform. Specifically, as geometric scaling of Si-based MOSFET technology becomes more challenging, the heterointegration of alternative area materials becomes an attractive option for increasing the innate carrier mobility of MOSFET channels. For many applications, it is desirable to incorporate alternative active-area materials having a low density of dislocation defects onto an insulator platform. As used herein, the term “alternative materials” refers to either a non-silicon semiconductor, or silicon with a different surface or rotational orientation compared to the underlying substrate. Such areas are suitable for use as active areas for MOSFETs or other electronic or opto-electronic devices.

Heterointegration of alternative materials has thus far been typically limited to the addition of SiGe alloys of small Ge content for use as source-drain contact materials or heterojunction bipolar transistor base layers. Since such layers are only slightly lattice-mismatched to Si, and since most modern Si MOSFET processes are compatible with these dilute SiGe alloys, few disruptions in the Si MOSFET integration sequence have been necessary. The drive for increased carrier mobility—and concomitant device drive current—wilt soon, however, necessitate the use of other, more highly lattice-mismatched materials for historically Si-based devices, requiring more disruptive changes to the traditional device integration flow.

In particular, heteroepitaxial growth can be used to fabricate many modern semiconductor devices where lattice-matched substrates are not commercially available or to potentially achieve monolithic integration with silicon microelectronics. Performance and, ultimately, the utility of devices fabricated using a combination of dissimilar semiconductor materials, however, depends on the quality of the resulting structure. Specifically, a low level of dislocation defects is important in a wide variety of semiconductor devices and processes, because dislocation defects partition an otherwise monolithic crystal structure and introduce unwanted and abrupt changes in electrical and optical properties. These, in turn, result in poor material quality and limited performance. In addition, the threading dislocation segments can degrade physical properties of the device material and can lead to a premature device failure.

As mentioned above, dislocation defects typically arise in efforts to epitaxially grow one kind of crystalline material on a substrate of a different kind of material—often referred to as a “heterostructure”—due to different crystalline lattice sizes of the two materials. This lattice mismatch between the starting substrate and subsequent layer(s) creates stress during material deposition that generates dislocation defects in the semiconductor structure. The stress field associated with misfit dislocations under certain conditions may cause formation of linear agglomerations of threading dislocations, termed a “dislocation pile-up.” This is generally defined as an area comprising at least three threading dislocations, with a threading dislocation density greater than 5×10⁶ cm⁻², and with threading dislocations substantially aligned along a slip direction such that the linear density of dislocations within the pile-up and along a slip direction is greater than 2000/cm. For example, the slip directions in SiGe materials are in-plane <110> directions. A high localized threading dislocation density present in dislocation pile-ups has a potentially devastating impact on the yield of devices formed in these regions and may render these devices unusable. Inhibiting the formation of dislocation pile-ups is, therefore, desirable.

To minimize formation of dislocations and associated performance issues, as mentioned above, many semiconductor heterostructure devices known in the art have been limited to semiconductor layers that have very closely—e.g. within 0.1%—lattice-matched crystal structures. In such devices a thin layer is epitaxially grown on a mildly lattice-mismatched substrate. As long as the thickness of the epitaxial layer is kept below a critical thickness for defect formation, the substrate acts as a template for growth of the epitaxial layer, which elastically conforms to the substrate template. While lattice-matching and near-matching eliminate dislocations in a number of structures, there are relatively few lattice-matched systems with large energy band offsets, limiting the design options for new devices.

Accordingly, there is considerable interest in heterostructure devices involving greater epitaxial layer thickness and greater lattice misfit than known approaches would allow. One known technique termed “epitaxial necking” was demonstrated in connection with fabricating a Ge-on-Si heterostructure by Langdo et al. in “High Quality Ge on Si by Epitaxial Necking,” Applied Physics Letters, Vol. 76, No. 25, April 2000. This approach offers process simplicity by utilizing a combination of selective epitaxial growth and defect crystallography to force defects to the sidewall of the opening in the patterning mask, without relying on increased lateral growth rates. This approach, however, generally requires relatively thick semiconductor layers, as well as relatively small lateral dimensions of the openings in the mask in order for the dislocations to terminate at its sidewalls, resulting in defect-free regions.

Several methods to fabricate non-Si semiconductors on insulator substrates have been previously reported, whereby transfer of SiGe material onto insulator substrate was achieved through bonding and splitting induced by hydrogen implantation and annealing. Generally, in these approaches, a relatively thick SiGe layer is deposited on a silicon substrate, which includes a graded SiGe buffer layer and a relaxed SiGe layer having a constant germanium concentration. Following surface planarization, hydrogen is implanted into the SiGe layer to facilitate wafer splitting. The Si/SiGe wafer is then bonded to an oxidized silicon substrate. The SiGe-on-oxide layers are separated from the rest of the couplet by thermal annealing, wherein splitting occurs along hydrogen-implantation-induced microcracks, which parallel the bonding interface.

A technique to form a SiGe-free strained silicon-on-insulator substrates has been also reported by T. A. Langdo and others in “Preparation of Novel SiGe-Free Strained Si on Insulator Substrates,” published in 2002 IEEE International SOI Conference Proceedings (October 2002). This technique is similar to approaches described above, except that a thin layer of epitaxial silicon is deposited on the SiGe layer before wafer bonding. After bonding and wafer splitting, the SiGe layer is removed by oxidation and HF etching, enabling the formation of very thin and uniform strained silicon-on-oxide surface.

Thus, there is a need in the art for versatile and efficient methods of fabricating semiconductor heterostructures, including alternative active-area materials disposed over a common insulator platform, that would address formation of interface defects in a variety of lattice-mismatched materials systems. There is also a need in the art for semiconductor devices utilizing a combination of integrated lattice-mismatched materials with reduced levels of substrate interface defects for improved functionality and performance.

### SUMMARY OF THE INVENTION

Heterointegration of alternative materials is desirable for various electronic and optoelectronic applications. For example, the heterointegration of III-V, II-VI materials and/or Ge with Si is an attractive path for increasing the functionality and performance of the CMOS platform. An economical solution to heterointegration could enable new fields and applications, such as replacing Si in CMOS transistors, particularly for critical-path logic devices. Heterointegration could significantly lower (a) channel resistance, due to the ultra-high mobility and saturation velocity afforded by various non-Si semiconductors, and (b) source/drain resistance, due both to high mobility and to the narrower bandgap of many non-Si semiconductors, with the narrower bandgap leading to a lower electrical resistance between the metal (or metal-alloy) contact and the semiconductor. Another new application could be the combination of Si CMOS logic with ultra-high speed RF devices, such as InP— or GaAs-based high electron-mobility transistor (HEMT) or heterojunction bipolar transistor (HBT) devices similar to those utilized for high-frequency applications today. Yet another application may be the combination of Si CMOS logic with opto-electronic devices, since many non-Si semiconductors have light emission and detection performance superior to Si.

Selective epitaxy is an attractive path for hetero-materials integration for several reasons. First, it facilitates adding the non-Si semiconductor material only where it is needed, and so is only marginally disruptive to a Si CMOS process performed on the same wafer. Also, selective epitaxy may allow multiple new materials to be combined on a common wafer, e.g., Ge for PMOS and InGaAs for NMOS. Furthermore, it is likely to be more economical than key alternative paths, e.g., layer transfer of global hetero-epitaxial films, especially for integrating materials with large lattice mismatch. In order to achieve integration of lattice-mismatched materials on an insulator, selective epitaxy can be supplemented by techniques employing ion implantation and bonding.

Accordingly, it is an object of the present invention to provide on-insulator semiconductor heterostructures with significantly minimized dislocation defects, and methods for their fabrication employing selective epitaxy and bonding.

As mentioned above, dislocation defects typically arise during epitaxial growth of one kind of crystal material on a substrate of a different kind of material due to differences in crystalline lattice sizes. This lattice mismatch between the starting substrate and subsequent layer(s) creates stress during material deposition that generates dislocation defects in the semiconductor structure. One known technique to control threading dislocation densities (“TDD”) in highly-mismatched epitaxial layers involves substrate patterning, which exploits the fact that the threading dislocations are constrained by geometry (i.e. that a dislocation cannot end in a crystal). If the free edge is brought closer to another free edge by patterning the substrate into growth areas, then it is possible to generally confine threading dislocations to a portion of the epitaxial layer proximate to its interface with the starting substrate, thereby minimizing the TDD in the remainder of the epitaxial layer.

Generally, in its various embodiments, the invention disclosed herein focuses on bonding patterned substrates with alternative active-area materials epitaxially formed thereon to a rigid platform, such as, for example, an insulator disposed over a handle wafer, and then removing the highly-defective interface areas along with the underlying substrates to produce alternative active-area regions disposed over the insulator and substantially exhausted of misfit and threading dislocations. As a result, the invention contemplates fabrication of semiconductor devices based on monolithic lattice-mismatched heterostructures on insulators long sought in the art but heretofore impractical due to dislocation defects.

In general, in one aspect, the invention disclosed herein features methods for forming a structure, including providing a first substrate including, or consisting essentially of, a first crystalline semiconductor material. A first insulator layer is formed over the first substrate, and at least one opening is defined in the first insulator layer extending to the first substrate. The opening is filled, at least partially, with an active-area material by, for example, selective epitaxy to form an active-area region surrounded by an insulator region. The method further includes forming a cleave area at a predetermined distance in relation to the interface between the first substrate and the active-area regions by, for example, implanting gaseous material into the active-area and the insulator regions. The active-area and the insulator regions are then bonded to a rigid platform, for example, a structure including a second insulator layer disposed over a second substrate including, or consisting essentially of, a second crystalline semiconductor material. The method further includes causing the bonded structure to split at least along the cleave area into a first portion and a second portion, the second portion including at least a portion of the active-area region bonded to the second insulator layer.

In various embodiments, the split within the bonded structure is caused by thermal annealing, e.g. at a temperature ranging from about 350° C. to 700° C. Optionally, a surface of the active-area region is planarized prior to implantation and bonding such that its surface is substantially coplanar with a surface of the insulator region. Also, following the split, an exposed surface of the second portion can be planarized to remove cleave-induced surface roughness and, if desired, reduce a thickness of the active-area region in the second portion to a desired value. In some embodiments, the second portion is annealed after the split at a temperature ranging from about 600° C. to about 900° C.

In some embodiments, the cleave area at least partially lies within the active-area and the insulator regions substantially parallel to the interface between the first substrate and the active-area region at a first predetermined distance therefrom, such that, following the split, the first portion includes portions of the active-area and the insulator regions disposed over the first substrate. In some implementations of these embodiments, a strained region is formed within the active-area region, such that the cleave area at least partially includes the strained region. In other embodiments, the cleave area at least partially lies within the first substrate substantially parallel to the interface between the first substrate and the active-area region at a second predetermined distance therefrom, such that, after causing the bonded structure to split into the first portion and the second portion, the second portion of the bonded structure includes a portion of the first substrate. Optionally, the remaining first crystalline semiconductor material is removed from the active-area and the insulator regions by post-annealing planarization and/or etching. In yet another embodiment of this aspect of the invention, the active-area material is epitaxially grown over the first substrate in a bottom portion of the opening, and then a third insulator layer is deposited in a top portion of the opening over the active-area material. The surface of the third insulator layer can be planarized prior to implantation and bonding such that the surface is substantially coplanar with a surface of the insulator region. In still other embodiments, the cleave area substantially coincides with or is proximate to the interface between the active-area material and the first substrate, such that the cleave area at least partially includes the interface between the first substrate and the active-area region.

Optionally, a strained semiconductor layer is deposited over the surface of the active-area region. Also, in some embodiments, prior to implantation and bonding, a dielectric material is deposited over the active-area material in the opening to form a buffer region above the active-area region. A surface of the buffer region extends at least to a surface of the first insulator layer. The surface of the buffer region is or can be made co-planar with the surface of the first insulator layer.

In this and other aspects of the invention, the rigid platform may include one or more layers of glass, quartz, plastic, polymer, or other dielectric material, either self-supporting or disposed over another layer. For example, the rigid platform can be a substrate including a second insulator layer disposed over a second substrate including, or consisting essentially of, a second crystalline semiconductor material. The first semiconductor and/or second semiconductor materials include, or consist essentially of, single-crystal silicon, germanium, a silicon-germanium alloy, and/or a III-V material. The first and second substrates may be, for example, a bulk silicon wafer, a bulk germanium wafer, a bulk III-V wafer such as gallium arsenide or indium phosphide, a semiconductor-on-insulator (SOI) substrate, or a strained semiconductor-on-insulator (SSOI) substrate. Also, the first and second insulator layers may include, or consist essentially of, silicon dioxide, aluminum oxide, silicon nitride, silicon carbide, and/or diamond, and may have a thickness of, e.g., 50-1000 nanometers. The third insulator layer can include, or consist essentially of, either the same material as the first and second insulator layers, or include a different material, such as, for example, a low-K dielectric material. Generally, the active-area material is a crystalline semiconductor material, such as a group IV element or compound, a III-V compound, and/or a II-VI compound. The group IV element may be carbon, germanium, and/or silicon, e.g., (110) silicon. The group IV compound may include silicon, germanium, tin, and/or carbon, e.g., silicon germanium (SiGe). The II-V compound may be, e.g., gallium arsenide (GaAs), indium arsenide (InAs), indium gallium arsenide (InGaAs), indium phosphide (InP), or indium antimonide (InSb), gallium nitride (GaN), and/or indium nitride (InN). The II-VI compound may be, e.g., zinc telluride (ZnTe), cadmium selenide (CdSe), cadmium telluride (CdTe), zinc sulfide (ZnS), and/or zinc selenide (ZnSe). Also, the first crystalline semiconductor material may have a first crystalline orientation and the active-area material comprises a third crystalline semiconductor material having a second crystalline orientation different from the first crystalline orientation. For example, the first crystalline semiconductor material may be (100) silicon and the active-area material may be (110) silicon. The gaseous material may include ions of hydrogen, helium, argon, krypton, and/or neon.

In general, in another aspect, the invention relates to a semiconductor structure that includes a substrate and, thereover, a patterned insulator layer defining at least one opening. The substrate can be a rigid platform that includes one or more layers of glass, quartz, plastic, polymer, or other dielectric material, either self-supporting or disposed over another layer, for example, including, or consisting essentially of, a crystalline semiconductor material. The structure further includes an active-area region formed in the opening and bonded to the substrate. The active-area region includes, or consists essentially of, an active-area material substantially exhausted of misfit and threading dislocations.

Various embodiments of this and other aspects of the invention include one or more of the following features. The substrate may include a base insulator layer disposed over the crystalline semiconductor material underneath the patterned insulator layer. The active-area region may have a buffer region that includes, or consists essentially of, a dielectric material and is disposed in the opening between the substrate and the active-area material. The active-area region may also have a strained semiconductor layer disposed over the active-area material. A dislocation pile-up density in the active-area material does not exceed about 1/cm, for example, is less than about 0.01/cm. Also, a threading dislocation density in the active-area material does not exceed about 10³ cm⁻², for example, is less than about 10² cm⁻².

In general, in other aspects, one or more electronic devices, such as, for example, a field-effect transistor (FET), such as a complementary metal-oxide-semiconductor FET (CMOSFET) or a metal-semiconductor FET (MESFET), or a non-FET device such as a diode, are defined including at least a portion of one or more of the active-area regions.

### BRIEF DESCRIPTION OF THE DRAWINGS

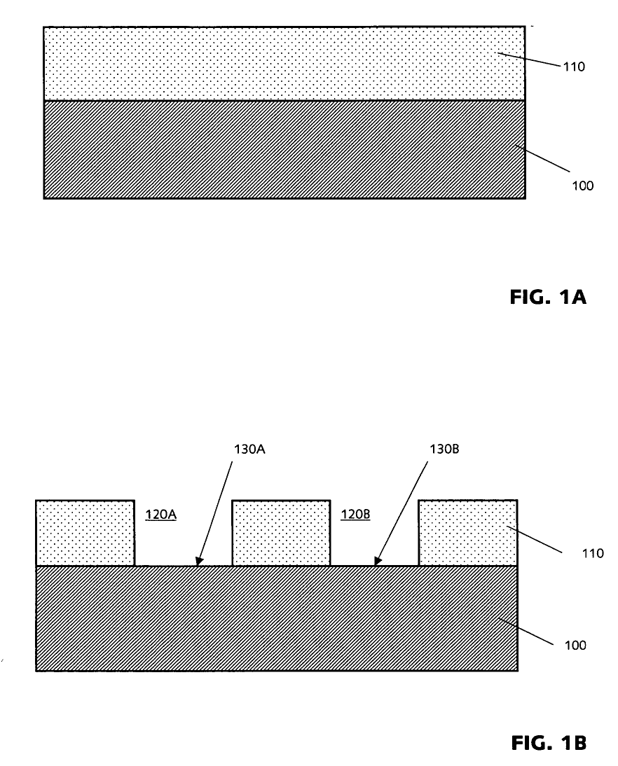

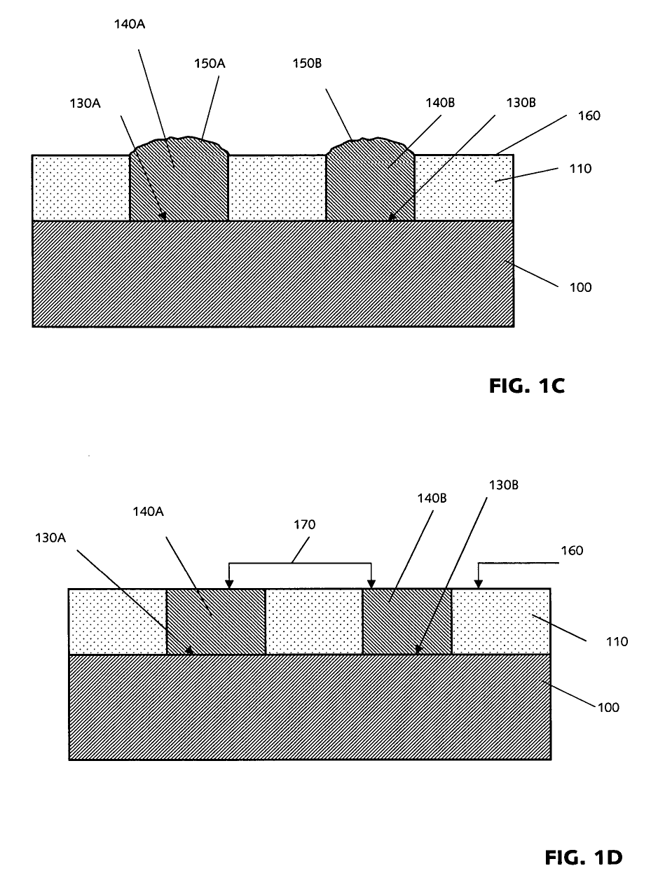

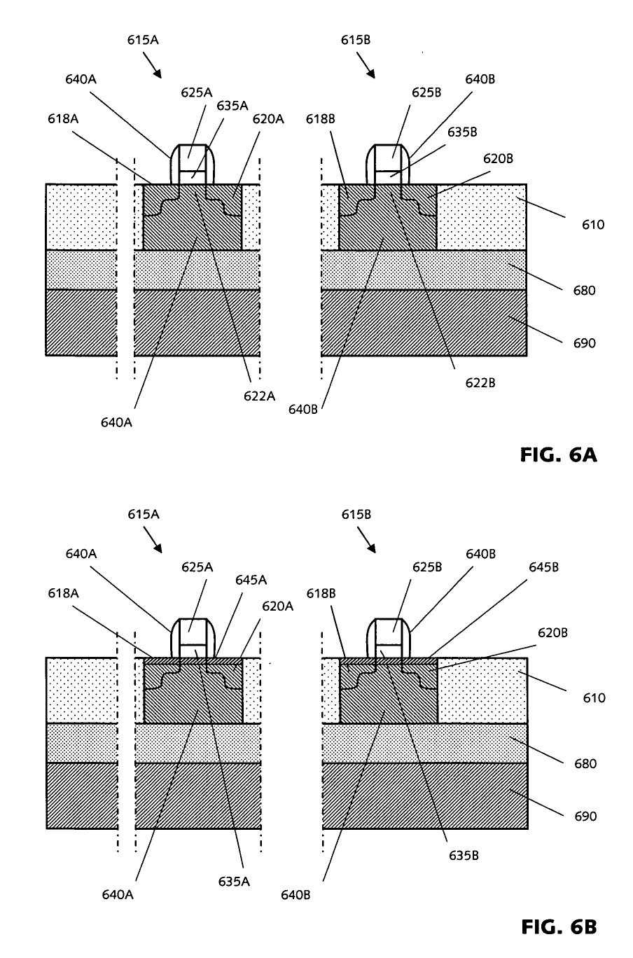

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which FIGS. 1A-1D, 2A-2C, 3A-3D, 4A-4B, and 5A-5C depict schematic cross-sectional side views illustrating formation of semiconductor structures including alternative active-area materials, and FIG. 6A-6B depict schematic cross-sectional side views of electronic devices fabricated over the semiconductor structures formed as illustrated in the preceding figures.

### DETAILED DESCRIPTION

In accordance with its various embodiments, the invention disclosed herein contemplates fabrication of monolithic lattice-mismatched semiconductor heterostructures disposed over an insulator platform with limited-area regions substantially exhausted of misfit and threading dislocations, as well as fabrication of semiconductor devices based on such lattice-mismatched heterostructures.

Referring to FIGS. 1A-1C, planar isolation regions may be utilized for the selective epitaxy of active-area materials. In one embodiment, a substrate 100 includes a crystalline semiconductor material. The substrate may be, for example, a bulk silicon wafer, a bulk germanium wafer, a bulk III-V wafer such as gallium arsenide or indium phosphide, a SOI substrate, or a SSOI substrate. An insulator layer 110 is formed over the substrate, as shown in FIG. 1A. The insulator layer may be, for example, silicon dioxide, aluminum oxide, silicon nitride, silicon carbide, or diamond, and may have a thickness of, e.g., 50-1000 nanometers (nm). The insulator layer may be formed by a deposition method, such as chemical vapor deposition (CVD), plasma-enhanced chemical vapor deposition (PECVD), or low-pressure chemical vapor deposition (LPCVD).

A mask (not shown), such as a photoresist mask, is formed over the insulator layer 110. The mask is patterned to expose at least a portion of the insulator layer. The exposed portion of the insulator layer is removed by, e.g., reactive ion etching (RIE), to define openings 120A and 120B and expose areas 130A and 130B of a top surface of the substrate 100, as shown in FIG. 1B. Each of the openings may have a width of, e.g., 50 nm-10 micrometers (μm) and a length of, e.g., 50 nm-10 μm. The height of the openings equals the thickness of the insulator layer. The openings correspond to the active areas of electronic or opto-electronic device(s) and the dimensions are selected accordingly.

Referring to FIGS. 1B-1C, in some embodiments, the openings 120A and 120B are filled with active-area materials by selective epitaxy, thereby forming active-area regions 140A and 140B surrounded by insulator regions of the insulator layer 110. Selective epitaxy may be performed by a deposition method such as atomic layer deposition (ALD) or CVD, for example, PECVD, LPCVD, ultra-high vacuum CVD, reduced-pressure CVD, or metalorganic CVD. Various deposition methods for forming active-area regions 140A and 140B may utilize techniques described in co-pending provisional application Ser. No. 60/681,940, incorporated herein by reference.

In many embodiments of the invention, the active-area regions 140A and 140B are formed selectively, i.e., the materials are deposited over the areas 130A, 130B of the crystalline semiconductor material of substrate 100 exposed by the openings, but are not substantially deposited or formed on the insulator layer 110. The active-area materials are crystalline semiconductor material, such as a group IV element or compound, a Ill-V compound, or a II-VI compound. The group IV element may be carbon, germanium, or silicon, e.g., (110) silicon. The group IV compound may include silicon, germanium, tin, or carbon, e.g., SiGe. The III-V compound may be, e.g., GaAs, InAs, InGaAs, InP, InSb, GaN, InN, or mixtures thereof. The II-VI compound may be, e.g., ZnTe, CdSe, CdTe, ZnS, and/or ZnSe. The active-area regions 140A and 140B may include, or consist essentially of, the same or different materials. Also, in some embodiments, one or more of the active-area regions may include, or consist essentially of, silicon. The lattice mismatch (or difference in equilibrium lattice constants) between the active-area materials and the crystalline semiconductor material of substrate 100 may, in some embodiments, exceed approximately 4%. In a particular embodiment, the lattice mismatch between the active-area materials and the crystalline semiconductor material of substrate is greater than approximately 8%. The density of misfit dislocations, which typically form as the active-area material relaxes to its equilibrium lattice constant and are present near the interface between the active-area material and the substrate, can exceed 1×10⁶ cm⁻², even exceeding 2×10⁶ cm⁻² or 4×10⁶ cm⁻² in some embodiments. These misfit dislocation defects are linear defects generally lying parallel to the interface and generally confined to a thin region near the interface.

Referring to FIG. 1C, after the openings 120A and 120B are filled with the active-area materials, portions 150A and 150B of the active-area materials may extend above a top surface 160 of the insulator layer 110 for various reasons, thereby forming a non-planar top surface. For instance, facets may form at a vertical interface between the semiconductor active area material and the insulator. Even without facets, a top surface of the active-area regions 140A and 140B may not be co-planar with a top surface of the insulator material, because of the difficulty of stopping the selective epitaxy precisely at the point that the openings are filled with the active-area materials. A non-planar surface may present subsequent processing difficulties, for example, compromise bondability of the active-area regions. Referring now to FIG. 1D, to address these potential difficulties, the portions 150A, 150B of the active area regions extending above the top surface of the insulator layer may be removed by, for example, planarization, so that surface 170 of the active-area regions is substantially coplanar with the top surface of the insulator layer. The active area material surface may be planarized by, for example, a chemical-mechanical polishing (CMP) step that is selective with respect to the insulator layer.

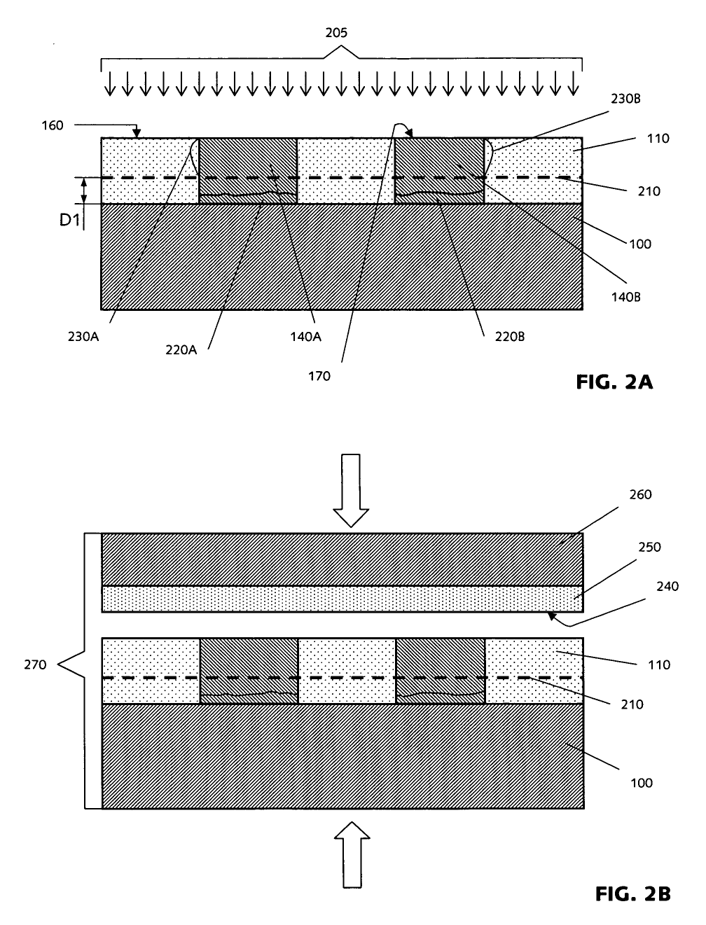

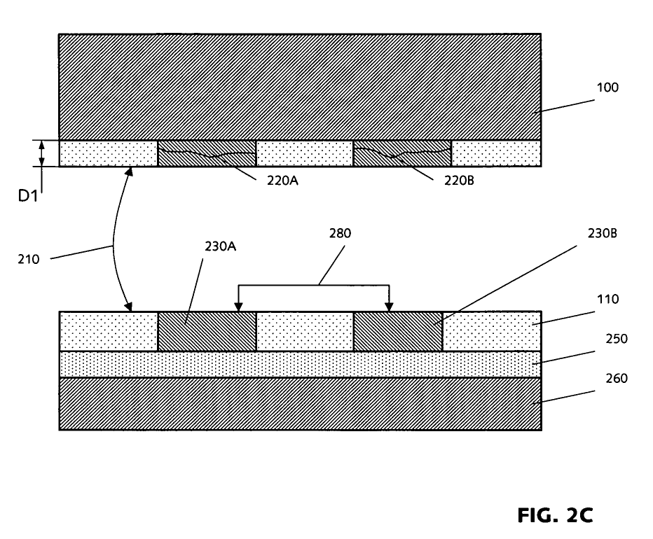

Referring now to FIG. 2A, in various embodiments, gaseous species 205 are introduced into the active-area regions 140A and 140B and the regions of the insulator layer 110 surrounding the active-area regions by, for example, ion implantation. The gaseous species may include, or consist essentially of, ions of hydrogen, helium, argon, krypton, and/or neon. In a particular embodiment, the gaseous species consist essentially of H⁺ ions. Implantation of the gaseous species is controlled such that the species penetrate the active-area and the insulator regions, forming a narrow cleave area 210 at a predetermined distance from the coplanar top surfaces 160, 170 of these regions. In one embodiment, the cleave area lies within the active-area and the insulator regions at a distance D1 above and substantially parallel to the interface between the substrate 100 and the active-area regions. The insulator regions may have smaller cross-sectional areas than the active-area regions 140A and 140B, and thus the cleaving behavior of the insulator regions will be substantially similar to that of the active-area regions. Additionally, after the split induced along the cleave area discussed in detail below, the insulator regions may function as isolation regions, e.g., shallow trench isolation regions, for devices subsequently formed in the active-area regions. The thickness of the cleave area depends on the parameters of the ion implantation, and, in many embodiments, is carefully controlled such that the cleave area is about 10-50% of the thickness of insulator layer 110. For example, for a thickness of insulator layer 110 of about 100 nm, the cleave area can be approximately 10-50 nm thick. In some embodiments, the implantation of the gaseous species to form cleave area 210 can be replaced or supplemented by another method of introducing gaseous species, such as diffusion or plasma-assisted gasification, e.g., plasma hydrogenation. As skilled artisans will appreciate, dislocation defects induced by the lattice mismatch between the crystalline semiconductor material of the substrate and the active-area material are generally concentrated in the active-area region proximate to the interface with the substrate. The heights of these highly-defective zones 220A, 220B of the active-area regions above the interface with the substrate 100 depends on, e.g., the degree of lattice mismatch between the materials, as well as epitaxial deposition conditions. By selecting the distance D1 to exceed the height of highly-defective zones 220A, 220B, portions 230A, 230B of the active-area region above the cleave area are substantially exhausted of misfit and threading dislocations. In one embodiment, portions 230A, 230B have a TDD at least three orders of magnitude lower than a TDD in the cleave area and/or highly-defective zones 220A, 220B. In another embodiment, portions 230A, 230B have a TDD at least five orders of magnitude lower than a TDD in the cleave area and/or the highly-defective zones. As skilled artisans readily appreciate, reduction in dislocation density of a semiconductor structure reduces leakage currents that contribute to the off-state current of a device formed thereon. Thus, as used herein, the active-area region being “substantially exhausted of misfit and threading dislocations” refers either to a complete absence of dislocations in this region or to the level thereof being sufficiently low so as not to meaningfully affect the performance of electronic device(s) at least partially incorporating this region. For example, in various embodiments of the invention, the off-state current of these devices is less than about 10⁻⁶ A/μm, preferably, less than about 10⁻⁸ A/μm, and more preferably 10⁻¹⁰ A/μm.

Referring to FIG. 2B, following ion implantation, top surfaces 160 and 170 of the active-area and the insulator regions are bonded to a surface 240 of an insulator layer 250 disposed over a semiconductor substrate 260 utilizing methods known in the art, e.g. as described in U.S. Pat. No. 6,602,613, incorporated herein by reference, thereby forming a structure 270. In one embodiment, to facilitate bonding, the surface 240 of the insulator layer and/or top surfaces 160, 170 is cleaned by a wet chemical cleaning process, e.g. by a hydrophilic surface preparation process. A suitable cleaning procedure for the prebonding surface preparation employs a modified megasonic RCA SC1 clean that includes application of a cleaning mixture including ammonium hydroxide, hydrogen peroxide, and water (NH₄OH:H₂O₂:H₂O) at a ratio of 1:4:20 at 60° C. for 10 minutes, followed by a deionized (DI) water rinse and spin dry. The wafer-bonding energy should be strong enough to sustain the subsequent layer transfer, as discussed below. In some embodiments, to increase the bond strength, top surfaces 160, 170 and/or the surface 240 of the insulator layer 250 are plasma-treated, either before, after, or instead of a wet clean. The plasma environment may include at least one of the following species: oxygen, ammonia, argon, nitrogen, diborane, and phosphine. After an appropriate cleaning step, top surfaces 160, 170 and the surface 240 are bonded together by bringing them in contact with each other at room temperature. The bond strength may be greater than 1000 mJ/m², achieved at a low temperature, such as, for example, less than 600° C. As skilled artisans will readily appreciate, bonding of top surfaces 160, 170 of the active-area and the insulator regions with the surface 240 of the insulator layer 250 generally requires that the root mean square surface roughness of these surfaces not exceed about 1 nm. Accordingly, in many embodiments, to improve bondability, the surfaces are planarized by CMP. In various embodiments, the insulator layer includes, or consists essentially of, silicon dioxide, aluminum oxide, silicon nitride, silicon carbide, or diamond, and may have a thickness of, e.g., 50-1000 nanometers (nm). The semiconductor substrate 260 may be, for example, a bulk silicon wafer, a bulk germanium wafer, a bulk III-V wafer such as gallium arsenide or indium phosphide, or a SOI substrate. In some embodiments, as mentioned above, semiconductor substrate 260 and insulator layer 250 may be replaced by another type of rigid platform, including but not limited to self-supporting substrates including or consisting essentially of glass, quartz, plastic, polymer, or any of the dielectrics discussed above in reference to insulator layer 250. The lattice mismatch between the active-area materials and the crystalline semiconductor material of substrate 260 may exceed approximately 4%. In a particular embodiment, the lattice mismatch between the active-area materials and the crystalline semiconductor material of substrate 260 exceeds approximately 8%.

In some embodiments, a top insulator layer (not shown) may be formed over the top surfaces 160, 170 of the active-area and insulator regions, resulting in insulator-on-insulator bonding. This top insulator layer may include, or consist essentially of, silicon dioxide, aluminum oxide, silicon nitride, silicon carbide, or diamond, and may have a thickness of, e.g., 50-1000 nm. In certain implementations of these embodiments, the top insulator layer is bonded directly to the substrate 260, without providing the insulator layer 250 therebetween.

In various embodiments, the structure 270 is then subjected to thermal annealing at a temperature ranging from about 350° C. to 700° C. for a period of time from about five minutes to about four hours. Referring to FIG. 2C, the thermal annealing induces a split in the structure 270 along the cleave area 210, separating the substrate 100 with portions of the insulator layer 110, and the active-area regions 140A, 140B having thickness D1 thereon from the portions 230A, 230B of the active-area regions surrounded by the insulator regions and bonded to the insulator layer 250. In some embodiments, a mechanical force and/or a jet of gas or liquid may be applied to the structure 270 in addition to or instead of the thermal annealing to induce the split. Following the split, in many embodiments, exposed surfaces 280 of the active-area regions are planarized or smoothed, e.g. using CMP, to remove cleave-induced surface roughness and, if desired, reduce a thickness of the active-area regions to a desired value. In various embodiments, a root mean square surface roughness of the surface 280 does not exceed about 1 nm. Thus, alternative active-area regions 230A and 230B disposed over the common insulator are obtained.

As mentioned above, in various embodiments of the invention, the alternative active-area regions 230A and 230B are substantially exhausted of misfit and threading dislocations. Defect densities can be measured using a standard chromic acid-based Schimmel etch as outlined, for example, in Journal of the Electrochemical Society 126:479 (1979), and an optical microscope operated in differential interference contrast (Nomarski) mode. TDDs can be calculated by counting the number of etch pits per unit area located away from dislocation pile-ups, yielding units of inverse area (cm⁻²). Dislocation pile-up densities can be calculated by measuring the total length of dislocation pile-ups per unit area, yielding units of inverse length (cm⁻¹). Defect densities may also preferably be confirmed by the use of a complementary characterization technique such as plan-view transmission electron microscopy. In various embodiments, a dislocation pile-up density in these active-area regions does not exceed about 20/cm, for example, is less than about 5/cm, preferably ranges from 0 to about 1/cm, and, more preferably, is less than about 0.01/cm. Also, TDD in these regions is less than about 10⁵ cm⁻², for example, less than about 10³ cm⁻², and, preferably, ranges between 0 and about 10² cm⁻².

In some embodiments, the structure 270 is further annealed at a temperature ranging from 600-900° C., e.g., at a temperature greater than about 800° C., to strengthen the bond between the surfaces 160, 170 and the surface 240.

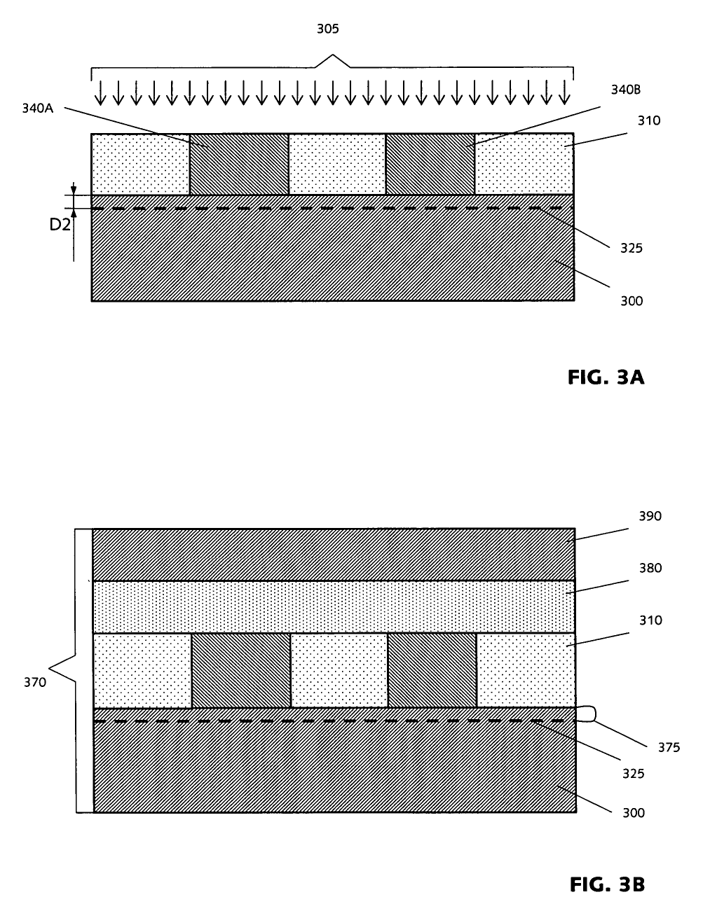

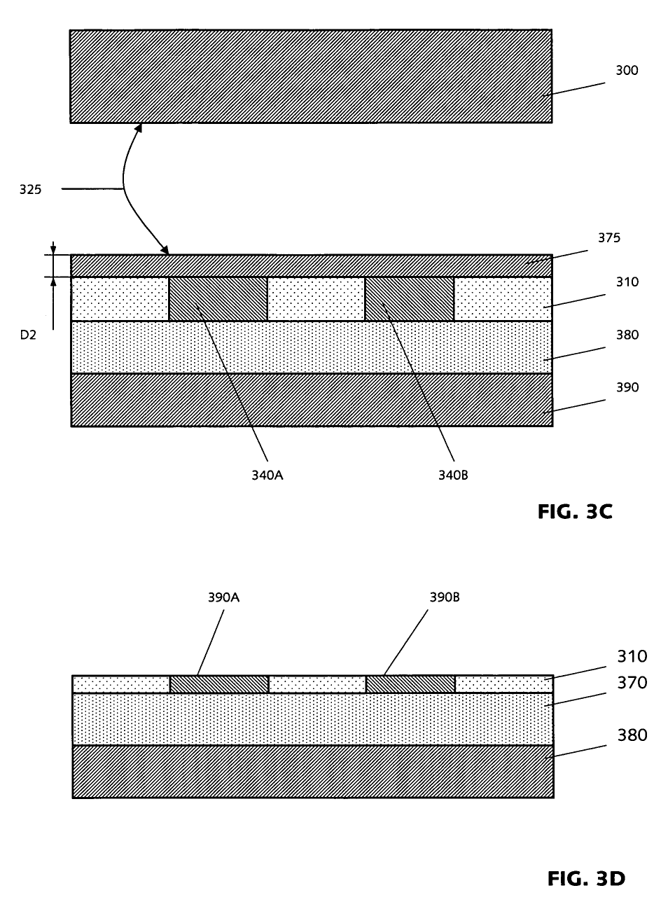

Referring now to FIGS. 3A-3D, in an alternative embodiment, co-planar active-area regions 340A and 340B and the regions of the insulator layer 310 surrounding the active-area regions are formed over the substrate 300 as described above in connection with FIGS. 1A-1C. Gaseous species 305, e.g. including, or consisting essentially of, ions of hydrogen, helium, argon, krypton, and/or neon, are introduced into the active-area and the insulator regions by, for example, ion implantation. In contrast with the embodiments described in connection with FIGS. 2A-2C, however, implantation of the gaseous species is controlled such that the species penetrate the substrate 300 through the active-area and the insulator regions, forming a narrow cleave area 325 at a predetermined distance D2 below the interface between the substrate and the active-area regions. The distance D2 may range, for example, from about 10 nm to about 1000 nm. As a result, the cleave area is disposed within a homogeneous zone of the crystalline material of the substrate 300. Following bonding and thermal annealing steps described above, the structure 370 is split along the cleave area 325, separating the substrate from a portion 375 thereof having the thickness D2 (and disposed over the active-area regions surrounded by the insulator regions) and bonded to an insulator layer 380, which itself, in turn, is disposed over a semiconductor substrate 390. As with the embodiments described above, the substrate 390 may be, for example, a bulk silicon wafer, a bulk germanium wafer, a bulk III-V wafer such as gallium arsenide or indium phosphide, or a SOI substrate. Then, the portion 375 of the substrate, as well as portions of the active-area and insulator regions disposed thereon, are removed by, for example, CMP to eliminate a highly-defective region proximate to the interface between the substrate and the active-area regions, as well as to obtain a desired thickness of the active-area regions. As a result, alternative active-area regions 330A and 330B disposed over the common insulator and substantially exhausted of misfit and threading dislocations are obtained. In many embodiments, a TDD of the alternative active-area regions is at least three (and, preferably, at least five) orders of magnitude lower than that present in the removed portion of the active-area material. In particular, in various embodiments, a dislocation pile-up density in these active-area regions does not exceed about 20/cm, for example, is less than about 1/cm, or, preferably, ranges from 0 to about 1/cm, and, more preferably, is less than about 0.01/cm. Also, TDD in these regions is less than about 10⁵ cm⁻², for example, less than about 10³ cm⁻², and, preferably, ranges from 0 to about 10² cm⁻².

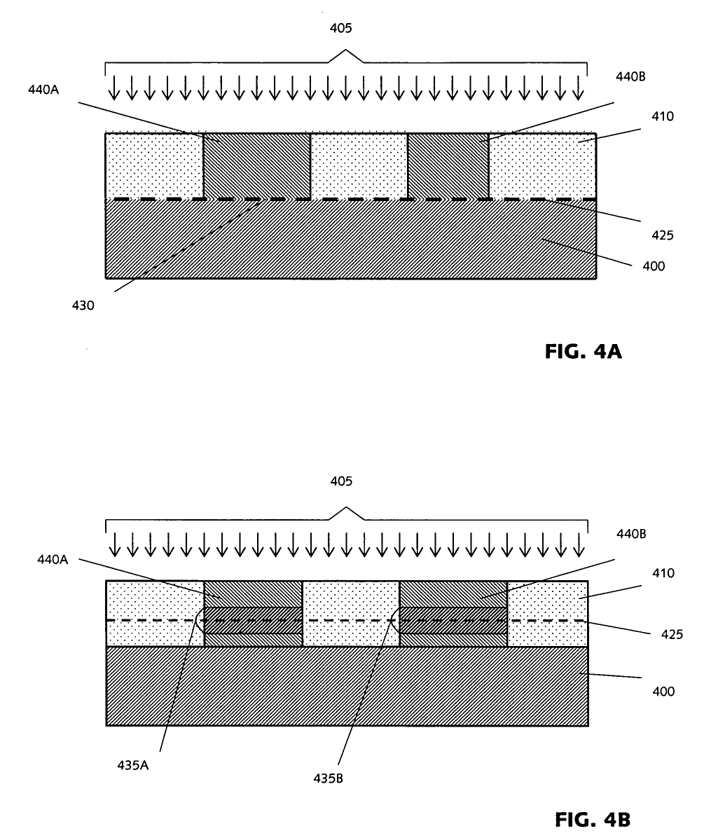

Referring to FIGS. 4A-4B, in other alternative embodiments, co-planar active-area regions 440A and 440B and the regions of the insulator layer 410 surrounding the active-area regions are formed over the substrate 400, as described above in connection with FIGS. 1A-1C. Gaseous species 405, e.g. including, or consisting essentially of, ions of hydrogen, helium, argon, krypton, and/or neon, are introduced into the active-area and the insulator regions by, for example, ion implantation. In contrast with the embodiments described in connection with FIGS. 2A-2C, however, in one embodiment, implantation of the gaseous species is controlled such that the species penetrate through the active-area and the insulator regions to an interface 430 between the substrate and the active-area regions, forming a narrow cleave area 425 that substantially coincides with the interface, as shown in FIG. 4A. Following bonding and thermal annealing steps described above, the resulting structure is split along the cleave area, separating the substrate from the active-area regions surrounded by the insulator regions and bonded to an insulator layer, which itself, in turn, is disposed over a semiconductor substrate. In one embodiment, in order to promote formation of the narrow cleave area 425 substantially coincident with the interface 430, a mild thermal anneal is performed after implantation of gaseous species 405. This anneal promotes diffusion of gaseous species 405 to interface 430 and any crystalline defects that may be present there. The anneal may be performed at, for example, 100-300° C. for a period of 1-30 minutes.

Referring now to FIG. 4B, in another embodiment, strained layers 435A and 435B are formed within the active-area regions during epitaxial deposition. For example, a layer of a semiconductor material that is lattice-mismatched to the active-area material can be selectively deposited over a portion of the active-area material to a thickness below the critical thickness of such lattice-mismatched material, and then the rest of the active-area material is deposited over the lattice-mismatched material. Preferably, the strained layer is tensilely, rather than compressively, strained to better accommodate implanted ions within its crystalline lattice. Implantation of the gaseous species is controlled such that the species penetrate through the active-area and the insulator regions to the strained layers, forming a narrow cleave area 425 that substantially coincides with the strained layers in the active-area regions. Following bonding and thermal annealing steps described above, the resulting structure is split along the cleave area, separating the substrate from a portion thereof disposed over the active-area regions surrounded by the insulator regions and bonded to an insulator layer, which itself, in turn, is disposed over a semiconductor substrate.

Following the split, exposed surfaces of the active-area regions can be planarized or smoothed, e.g. using CMP, to remove cleave-induced surface roughness and, if desired, reduce a thickness of the active-area regions to a desired value. As a result, alternative active-area regions disposed over the insulator and substantially exhausted of misfit and threading dislocations are obtained. Notably, in these embodiments, employing the interface area between the substrate and the active-area regions or the deliberately-introduced strained layer as a target height for the cleave area improves control over penetration of the implanted ions and associated thickness of the active-area regions. Also, because of the high concentration of dislocation defects in the interface area and the strained layer, a lesser concentration of implanted ions and/or a more efficient (e.g., lower) thermal budget is needed to effect cleave-induced split within the bonded structure. In addition, any portion of strained layers 435A, 435B remaining after splitting and planarization may be used in subsequently formed devices, as, for example, transistor channel regions with enhanced mobility.

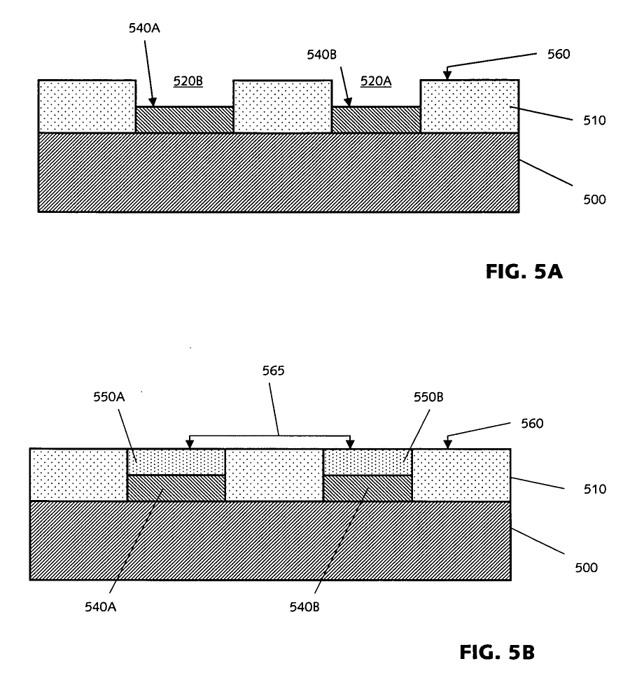

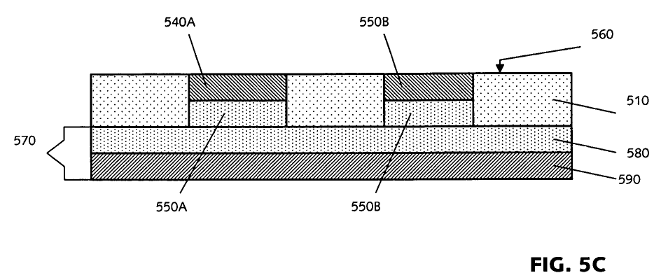

Referring to FIGS. 5A-5C, in certain implementations of the embodiments described above with reference to FIGS. 1B-1C, the epitaxially deposited active area material(s) only partially fill openings 520A and 520B defined in an insulator layer 510 and extending to the substrate 500. Thus, top surfaces of active-area regions 540A and 540B do not reach to the top surface 560 of the insulator layer. The remaining space in the openings can be left empty, or, as shown in FIG. 5B, filled with a dielectric material forming buffer regions 550A and 550B over the active-area regions. The dielectric material may be deposited over the entire surface of active-area regions 540A, 540B and top surface 560 of the insulator layer. The structure may then be planarized such that any dielectric material formed over top surface 560 of the insulator layer is removed, and the dielectric material remains only over active-area regions 540A, 540B. Should any dielectric material remain over top surface 560 of the insulator layer, it will at least be co-planar with a top surface of buffer regions 550A, 550B. The dielectric material may include, or consist essentially of, silicon dioxide, aluminum oxide, silicon nitride, and/or silicon carbide, and can be the same material used for the insulator layer 510, or a different material. In some embodiments, the dielectric material is a low-K dielectric with a lower dielectric constant than that of silicon dioxide; such materials are particularly suitable for subsequent manufacturing of FDSOI devices. The dielectric material can be deposited, such as by CVD or ALD, or spun on from a solution. Suitable thicknesses for the dielectric material range from 10 to 200 nm. Examples of suitable low-K dielectrics include silsequioxane-based polycyclic oligomers or polymers such as hydroxyl silsequioxane (HSQ) or methyl silsequioxane (MSQ); Black Diamond, available from Applied Materials, Inc. of Santa Clara, Calif.; CORAL, available from Novellus Systems Inc. of San Jose, Calif.; other organosilicate glasses or carbon doped oxides (SiCOH); SiLK, available from Dow Chemical Co. of Midland, Mich.; benzocyclobutene (BCB); porous silica; polymer foams; and GX-3, HOSP, and NANOGLASS, available from Honeywell International Inc. of Sunnyvale, Calif.

Still referring to FIG. 5B, following deposition of the dielectric material in the openings 520A and 520B, top surface 565 of the dielectric buffer regions is optionally planarized for improved bondability. Then, with reference to FIG. 5C, the steps of forming a cleave area by ion implantation, bonding, and annealing with optional post-annealing planarization of the active-area regions are performed in a manner similar to that described above in connection with FIGS. 2A-2C, 3A-3D, and 4A-4B, forming the active-area regions of desired thickness disposed over the dielectric regions 550. The dielectric buffer regions are bonded to a handle wafer 570, including a semiconductor substrate 590 having an optional insulating layer 580 thereover. Thus, in the implementations described with reference to FIGS. 5A-5C, a final thickness of the active-area regions is established prior to the bonding steps. Also, in some versions, having dielectric buffer regions of the active-area regions generally facilitates bondability to the insulator layer 590.

In many applications, various electronic devices can be formed in the on-insulator portions of the active-area regions. Referring to FIG. 6A, in some embodiments, active area regions 640A, 640B are formed over a common insulator layer 680 disposed over a semiconductor wafer 690, as described above in connection with FIGS. 2A-2C, 3A-3C, or 4A-4B. Then, an n-MOS transistor 615A and a p-MOS transistor 615B are formed, having source regions 618A, 618B, drain regions 620A, 620B, and channel regions 622A, 622B disposed in the active-area material(s). The insulator regions 610 function as isolation regions, e.g., shallow trench isolation regions, for transistor 615A, 615B.

Additional semiconductor layers may be formed above the active areas on the insulator. For example, referring to FIG. 6B, in some embodiments, thin strained semiconductor layers 645A, 645B are formed atop the active areas and can be subsequently used as channels for transistors. In one embodiment, the layers 645A, 645B are tensilely strained and formed of silicon. In this embodiment, these layers may be formed in a dedicated chamber of a deposition tool that is not exposed to the source gases for the epitaxial growth of the active-area material, thereby avoiding cross-contamination and improving the quality of the interface between the strained layers and the active-area regions. Furthermore, strained layers 645A, 645B may be formed from one or more isotopically pure precursors. Isotopically pure materials have better thermal conductivity than conventional materials consisting of mixtures of different isotopes. Higher thermal conductivity may help dissipate heat from devices subsequently formed on these strained layers, thereby maintaining the enhanced carrier mobilities these layers provide. In other embodiments, the strained layers may be formed of SiGe, or at least one group II, group III, group V, and/or group VI element. In various embodiments, the strained layers have a thickness of, for example, 50-500 Å, preferably below 300 Å.

Further processing steps may include the formation of gate dielectric layers 635A, 635B, the deposition of gate electrode materials 625A, 625B, and the definition of gates by, e.g., dry etching, such that spacers 642A, 642B are formed adjacent to the gate dielectric and gate electrode layers. The source and drain regions may be defined by an ion implantation step. Interlayer dielectrics may be formed over gate, source, and drain, and contact holes may be defined. Metal layers may be deposited in the contact holes and over the structure. In some embodiments, the interlayer dielectrics, for example, including or consisting essentially of, silicon nitride, are used to induce strain on at least one of channel regions 622A, 622B.

Suitable methods for fabrication of CMOS devices, e.g. those having different n- and p-active areas, are described in co-pending provisional application Ser. No. 60/702,363, incorporated herein by reference. The resulting transistors may be, for example, a field-effect transistor (FET), such as a complementary metal-oxide-semiconductor FET (CMOSFET) or a metal-semiconductor FET (MESFET). In an alternative embodiment, the device is a non-FET device such as a diode. The diode device could be a light detecting device (photodiode), or a light emitting device (either a light-emitting diode, or a laser diode). In an alternative application, the device is a bipolar junction transistor.

Other embodiments incorporating the concepts disclosed herein may be used without departing from the spirit of the essential characteristics of the invention or the scope thereof. The foregoing embodiments are therefore to be considered in all respects as only illustrative rather than restrictive of the invention described herein. Therefore, it is intended that the scope of the invention be only limited by the following claims.

1. A method for forming a structure, the method comprising:
providing a first substrate comprising a first crystalline semiconductor material;
forming a first insulator layer over the first substrate;
defining at least one opening in the first insulator layer extending to the first substrate;
at least partially filling the opening with an active-area material to form an active-area region;
forming a cleave area at a predetermined distance relative to an interface between the first substrate and the active-area region;
bonding the active-area region to a second insulator layer disposed over a second substrate to form a bonded structure, the second substrate comprising a second crystalline semiconductor material; and
causing the bonded structure to split at least along the cleave area into a first portion and a second portion, the second portion comprising at least a portion of the active-area region bonded to the second insulator layer.

2. The method of claim 1 wherein at least one of the first and the second crystalline semiconductor materials comprises at least one of silicon, germanium, a silicon-germanium alloy, and a III-V material.

3. The method of claim 1 wherein at least one of the first and the second substrates comprises a bulk silicon wafer, a bulk germanium wafer, a bulk III-V wafer, a semiconductor-on-insulator substrate, or a strained semiconductor-on-insulator substrate.

4. The method of claim 1 wherein at least one of the first and the second insulator layers comprises silicon dioxide, aluminum oxide, silicon nitride, silicon carbide, diamond, or a combination thereof.

5. The method of claim 1 wherein at least one of the first and the second insulator layers is formed by chemical vapor deposition, plasma-enhanced chemical vapor deposition, low pressure chemical vapor deposition, or atomic layer deposition.

6. The method of claim 1 wherein a thickness of at least one of the first and the second insulator layers is selected from a range of about 50 nm to about 1000 nm.

7. The method of claim 1 wherein the active-area material comprises at least one of a group IV element, III-V compound, a II-VI compound, and a combination thereof.

8. The method of claim 7 wherein the active-area material comprises gallium arsenide, indium arsenide, indium gallium arsenide, indium phosphide, indium antimonide, gallium nitride, indium nitride, or a combination thereof.

9. The method of claim 7 wherein the active-area material comprises zinc telluride, cadmium selenide, cadmium telluride, zinc sulfide, zinc selenide, or a combination thereof.

10. The method of claim 7 wherein the active-area material comprises silicon, germanium, a silicon-germanium alloy, tin, carbon, or a combination thereof.

11. The method of claim 1 wherein the first crystalline semiconductor material has a first crystalline orientation and the active-area material comprises a third crystalline semiconductor material having a second crystalline orientation the second crystalline orientation being different from the first crystalline orientation.

12. The method of claim 11 wherein the first crystalline semiconductor material comprises (100) silicon and the active-area material comprises (110) silicon.

13. The method of claim 1 wherein the cleave area is formed by implanting a gaseous material into at least the active-area region.

14. The method of claim 13 wherein the gaseous material comprises ionized hydrogen, helium, argon, krypton, neon, or a mixture thereof.

15. The method of claim 1 wherein a thickness of the first insulator layer is about 100 nm and a thickness of the cleave area is selected from a range of about 10 nm to about 50 nm.

16. The method of claim 1, further comprising, prior to bonding the active-area region to the second insulator layer, planarizing a surface of the active-area region such that the surface is substantially coplanar with a surface of the first insulator layer.

17. The method of claim 1 wherein the cleave area at least partially lies within the active-area region substantially parallel to the interface between the first substrate and the active-area region at a first predetermined distance therefrom.

18. The method of claim 17, further comprising forming a strained region within the active-area region, wherein the cleave area at least partially includes the strained region.

19. The method of claim 1 wherein the cleave area at least partially lies within the first substrate substantially parallel to the interface between the first substrate and the active-area region at a second predetermined distance therefrom, such that, after causing the bonded structure to split into the first portion and the second portion, the second portion of the bonded structure comprises a portion of the first substrate.

20. The method of claim 19, further comprising removing the portion of the first substrate.

21. The method of claim 1 wherein the cleave area at least partially includes the interface between the first substrate and the active-area region.

22. The method of claim 1, further comprising, prior to bonding the active-area region to the second insulator layer, forming a third insulator layer over the active-area region and the first insulator layer.

23. The method of claim 1 wherein the step of causing the bonded structure to split at least along the cleave area comprises annealing the bonded structure at a first temperature selected from a range of about 350° C. to about 700° C.

24. The method of claim 1, further comprising, after causing the bonded structure to split into the first portion and the second portion, at least one of:
(a) reducing a thickness of the active-area region in the second portion to a predetermined thickness; and
(b) planarizing a surface of the active-area region in the second portion to reduce a roughness thereof.

25. The method of claim 24, further comprising annealing the second portion at a second temperature selected from a range of about 600° C. to about 900° C.

26. The method of claim 24, further comprising depositing a strained semiconductor layer over the surface of the active-area region.

27. The method of claim 1, further comprising depositing a dielectric material over the active-area material in the opening to form a buffer region above the active-area region, a surface of the buffer region extending at least to a surface of the first insulator layer.

28. The method of claim 27 wherein the surface of the buffer region is co-planar with the surface of the first insulator layer.

29. The method of claim 1, further comprising defining an electronic device including at least the portion of the active-area region in the second portion of the bonded structure.

30. The method of claim 1 wherein a lattice mismatch between the active-area material and at least one of the first crystalline semiconductor material and the second crystalline semiconductor material is greater than approximately 4%.

31. The method of claim 30 wherein the lattice mismatch is greater than approximately 8%.

32. The method of claim 1 wherein the opening is at least partially filled with the active-area material by selective epitaxy.

33. The method of claim 32 wherein formation of the active-area region by selective epitaxy comprises chemical vapor deposition or atomic layer deposition.

34. The method of claim 33 wherein formation of the active-area region by selective epitaxy comprises plasma-enhanced chemical vapor deposition, low pressure chemical vapor deposition, ultra-high vacuum chemical vapor deposition, reduced pressure chemical vapor deposition, or metalorganic chemical vapor deposition.

35. A method for forming a structure, the method comprising:
providing a first substrate comprising a first crystalline semiconductor material;
forming a first insulator layer over the first substrate;
defining at least one opening in the first insulator layer extending to the first substrate;
at least partially filling the opening with an active-area material to form an active-area region;
forming a cleave area at a predetermined distance relative to an interface between the first substrate and the active-area region;
bonding the active-area region to a rigid platform to form a bonded structure; and
causing the bonded structure to split at least along the cleave area into a first portion and a second portion, the second portion comprising at least a portion of the active-area region bonded to the rigid platform.

36. The method of claim 35 wherein the opening is at least partially filled with the active-area material by selective epitaxy.

37. The method of claim 35 wherein the rigid platform is a self-supporting insulator layer comprising glass, quartz, silicon dioxide, aluminum oxide, silicon nitride, silicon carbide, diamond, polymer material, or a combination thereof.
